(19) United States
(12) Patent Application Publication
(10) Pub. No.: US 2020/0305296 A1
(43) Pub. Date: Sep. 24, 2020

(54) CONNECTOR-EQUIPPED CASE, CONNECTOR-EQUIPPED WIRE HARNESS, AND ENGINE CONTROL UNIT

(71) Applicants: AUTONETWORKS TECHNOLOGIES, LTD., Yokkaichi (JP); SUMITOMO WIRING SYSTEMS, LTD., Yokkaichi (JP); SUMITOMO ELECTRIC INDUSTRIES, LTD., Osaka-shi (JP)

(72) Inventors: Aya TEZUKA, Yokkaichi (JP); Tatsuo HIRABAYASHI, Yokkaichi (JP)

(73) Assignees: AUTONETWORKS TECHNOLOGIES, LTD., Yokkaichi (JP); SUMITOMO WIRING SYSTEMS, LTD., Yokkaichi (JP); SUMITOMO ELECTRIC INDUSTRIES, LTD., Osaka-shi (JP)

(21) Appl. No.: 16/815,318

(22) Filed: Mar. 11, 2020

(30) Foreign Application Priority Data
Mar. 22, 2019 (JP) 2019-055700

(51) Int. Cl. H05K 5/00; H01R 13/516; B60R 16/02

(52) U.S. Cl. CPC H05K 5/0069; B60R 16/0207; H01R 13/516; H05K 5/0034

(57) ABSTRACT

A connector-equipped case that includes a case that includes a through hole; and a connector fixed to the case, the connector including: a core that supports a plurality of terminals; and a hood that is formed by forming a region around the through hole of the case and a portion of the core in one piece, wherein a constituent material of the hood is a resin composition containing polybutylene terephthalate and polyethylene terephthalate.

### BACKGROUND

The present disclosure relates to a connector-equipped case, a connector-equipped wire harness, and an engine control unit.

As an engine control unit for a vehicle, JP 2017-004698A discloses a structure including an enclosure made of metal that stores a circuit board, and a connector that is fixed to the enclosure using a silicone-based moisture-curable adhesive. The enclosure includes a case having a side surface opening, and a cover that covers an upper surface opening of the case. The connector includes multiple pin-shaped terminals and a housing made of resin that supports the terminals. An intermediate portion of the housing is interposed between the case and the cover in a state of being arranged in the side surface opening. As a result, a portion of the housing is arranged in the enclosure, and the remaining portion is arranged outside of the enclosure. A wire harness is connected to the above-described connector. A circuit board and an electronic device included in the engine are electrically connected to each other via the wire harness.

### SUMMARY

It is desired that the size and weight of an engine control unit (ECU) including a wire harness are reduced.

Conventionally, an ECU that performs control of fuel injection and the like is arranged at a position located away from an engine, such as a corner of an engine room of an automobile. For this reason, a wire harness connecting the ECU and the engine is long. It was discovered that with an ECU having the above-described conventional structure, cracks may occur in the connector when the above-described ECU is arranged near the engine in order to shorten the wire harness.

An exemplary aspect of the disclosure provides a connector-equipped wire harness in which cracks are not likely to occur in a connector portion. Also, another exemplary aspect of the disclosure provides a connector-equipped wire harness and an engine control unit in which cracks are not likely to occur in a connector portion.

A connector-equipped case of the present disclosure includes: a case that includes a through hole; and a connector fixed to the case, the connector including: a core that supports a plurality of terminals; and a hood that is formed by forming a region around the through hole of the case and a portion of the core in one piece, wherein a constituent material of the hood is a resin composition containing polybutylene terephthalate and polyethylene terephthalate.

A connector-equipped wire harness of the present disclosure includes: the connector-equipped case of the present disclosure; and a wire harness that is connected to ends of the terminals. The overall length of the wire harness is less than 800 mm.

A connector-equipped engine control unit of the present disclosure includes: the connector-equipped case of the present disclosure or the connector-equipped wire harness of the present disclosure; and the circuit board that is stored in the case and is connected to the ends on one side of the terminals.

In the connector-equipped case of the present disclosure, the connector-equipped wire harness of the present disclosure, and the engine control unit of the present disclosure, cracks are not likely to occur in the connector portion.

### BRIEF DESCRIPTION OF THE DRAWINGS

FIG. 1 is a schematic perspective view showing a connector-equipped case of an embodiment.

FIG. 2 is a schematic side view showing a connector-equipped wire harness and an engine control unit of an embodiment.

FIG. 3 is a partial cross-sectional view showing a state in which the connector-equipped case of the embodiment shown in FIG. 1 has been cut along cutting line (III)-(III).

FIG. 4 is an exploded perspective view illustrating a method for manufacturing the connector-equipped case of the embodiment.

FIG. 5 is a schematic view showing an enlarged view of a location provided with a one-dot chain line circle (V) in the connector-equipped case of the embodiment shown in FIG. 1.

FIG. 6A is a diagram illustrating a test piece for a shear tension test, and shows a state prior to injection molding.

FIG. 6B is a plan view of a test piece for a shear tension test.

FIG. 6C is a side view of a test piece for a shear tension test.

### DETAILED DESCRIPTION OF EMBODIMENTS

### Description of Embodiments of the Present Disclosure

First, embodiments of the present disclosure will be listed and described.

(1) The connector-equipped case according to an aspect of the present disclosure includes:

a case; and

a connector portion fixed to the case.

The case includes a through hole, the connector portion includes:
a core portion that supports a plurality of terminals; and
a hood portion that is formed by forming a region around the through hole of the case and a portion of the core portion in one piece, and

a constituent material of the hood portion is a resin composition containing polybutylene terephthalate and polyethylene terephthalate.

With the ECU of the above-described conventional structure, the housing of the connector is manufactured independently of the case of the enclosure. Also, the above-described conventional housing is manufactured using one instance of injection molding. In contrast to this, the connector-equipped case of the present disclosure includes two members, namely a core portion and a hood portion. Also, these two members are manufactured in a step-wise manner. Also, with the connector-equipped case of the present disclosure, the case includes a through hole, and the hood portion is provided in contact with the case in a region near the through hole of the case and is integrated with the core portion through the through hole. This connector-equipped case of the present disclosure is completely different from the above-described conventional structure.

Furthermore, with the connector-equipped case of the present disclosure, the constituent material of the hood portion is a specific resin composition that contains polybutylene terephthalate (PBT) and polyethylene terephthalate (PET).

Even if the above-described specific resin composition is provided in contact with a metal, for example, an aluminum-based alloy, and is subjected to a heat cycle, cracks are not likely to occur (see later-described Test Example 1). One reason for this is thought to be that toughness is increased since, unlike the conventional resin composition (e.g., PBT) of the connector, the specific resin composition contains PET in addition to PBT. Cracks are not likely to occur in the hood portion constituted by this specific resin composition, even if the hood portion is arranged in a usage environment that is repeatedly subjected to a heat cycle, such as a location near an engine, for example, a location directly above an engine. In particular, cracks are not likely to occur at a location of the hood portion that is provided in contact with a metal. Also, it is thought that when cracks occur, the cracks are not likely to develop even in a usage environment that is repeatedly subjected to vibration, such as a location near an engine. Accordingly, the connector-equipped case of the present disclosure can be arranged directly above an engine, for example.

Also, the above-described specific resin composition is not likely to warp even if provided in contact with a metal (see later-described Test Example 2). For this reason, the hood portion is not likely to separate from the case, and it is possible to favorably maintain a state in which the hood portion is integrated with the case.

Furthermore, when the connector-equipped case of the present disclosure is arranged at a location near an engine, such as a location directly above an engine, the length of the wire harness connected to the connector portion can be made shorter compared to the case where the connector-equipped case is arranged in a corner of an engine room or the like. This is because an electronic device (e.g., a coil for a fuel injector, a spark plug, etc.) that is provided in the engine and to which the wire harness is connected is typically arranged above the engine. Due to shortening the wire harness, the connector-equipped case of the present disclosure contributes to a reduction in the size and weight of the engine control unit including the wire harness. If the connector-equipped case of the present disclosure is used in a control unit for a vehicle-mounted engine, the connector-equipped case contributes to a reduction in the size and weight of the vehicle-mounted components, and consequently, to an improvement in fuel efficiency.

The above-described specific resin composition mainly contains thermoplastic resin. For this reason, the hood portion can be easily manufactured using injection molding. Also, for example, if the resin composition is injected from outside of the case to the outer peripheral surface of the case and the resin composition fills the case through a through hole of the case, the hood portion can be molded and the hood portion and the core portion can be easily integrated. Furthermore, if an adhesive layer is included between the hood portion and the case in order to improve sealability, an adhesive layer can be formed by curing the adhesive using the pressure and heat obtained during injection molding, and the hood portion and the case can be bonded by the adhesive layer. This connector-equipped case of the present disclosure can reduce the number of steps, and has excellent manufacturability as well.

(2) As one example of the connector-equipped case of the present disclosure, a mode is given in which

in the resin composition, the content of the polybutylene terephthalate is 150 parts by mass or more and 400 parts by mass or less, with respect to 100 parts by mass of the polyethylene terephthalate.

In the above-described mode, the PET is suitably included in the PBT. For this reason, cracks are not likely to occur in the hood portion. Also, in the above-described mode, warping is not likely to occur, and an excellent injection molding property is achieved.

(3) As one example of the connector-equipped case of the present disclosure, a mode is given in which

the resin composition further contains a filler, and

the filler includes at least one of glass fibers and glass flakes.

In the mode in which glass fibers are included, the strength of the hood portion is easily increased. In the mode in which glass flakes are included, the hood portion is not likely to warp.

(4) As one example of the connector-equipped case according to (3) above, a mode is given in which

the content of the filler is 20 parts by mass or more and 60 parts by mass or less, with respect to 100 parts by mass of the resin composition.

In the above-described mode, the filler is suitably included. For this reason, the strength of the hood portion is more likely to be increased. If glass flakes are included, the hood portion is even less likely to bend.

(5) As one example of the connector-equipped case of the present disclosure, a mode is given in which

the resin composition further contains an elastomer.

In the above-described mode, the toughness of the hood portion is further improved using elastomer. For this reason, cracks are even less likely to occur in the hood portion. Also, the hood portion is even less likely to warp.

(6) As one example of the connector-equipped case of the present disclosure, a mode is given in which

a phase structure of the resin composition is a sea-island structure, and

a sea portion of the sea-island structure mainly contains the polybutylene terephthalate, and island portions of the sea-island structure mainly contain the polyethylene terephthalate.

In the above-described mode, it can be said that the PET is evenly dispersed in the PBT. For this reason, in the above-described mode, a favorable injection molding property is obtained due to mainly containing PBT, and an effect of reducing the occurrence of cracks and an effect of reducing warping are likely to be obtained due to including PET. For these reasons, cracks are less likely to occur in the hood portion. Also, the hood portion is less likely to warp.

(7) As one example of the connector-equipped case of the present disclosure, a mode is given in which

a constituent material of the core member is the resin composition.

In the above-described mode, the state in which the core portion and the hood portion are integrated is favorably maintained. Also, if the hood portion is manufactured through injection molding, the core portion and the hood portion can be favorably bonded using the heat obtained during injection molding, or the like. In this respect, the above-described mode has more excellent manufacturability.

(8) As one example of the connector-equipped case of the present disclosure, a mode is given in which

the case is a die-cast member.

The case included in the above-described mode can be easily manufactured using die casting. The above-described mode has more excellent manufacturability since the case is easy to manufacture.

(9) As one example of the connector-equipped case according to (8) above, a mode is given in which

a constituent material of the case is an aluminum-based alloy.

In the above-described mode, the constituent material of the case is more lightweight compared to the case of using an iron-based alloy or the like, for example. Also, the case has excellent thermal conductivity. For this reason, heat is not likely to be trapped in the connector portion. As a result, thermal shock accompanying a heat cycle is mitigated. Accordingly, cracks are less likely to occur in the hood portion.

(10) As one example of the connector-equipped case according to (9) above, a mode is given in which

the aluminum-based alloy contains Si in an amount of 1 mass % or more and 30 mass % or less.

The case included in the above-described mode has excellent castability. The above-described mode has more excellent manufacturability since the case is easy to manufacture. Also, in general, a die-cast member and a resin composition are not likely to stick to each other when resin is injection-molded (insert-molded) in the die-cast member composed of an aluminum-based alloy containing Si. In contrast to this, with the connector-equipped case of the present disclosure, in which the hood portion is composed of the above-described specific resin composition, the case and the hood portion are likely to stick to each other even if the hood portion is injection-molded in the case composed of the die-cast member.

(11) As one example of the connector-equipped case of the present disclosure, a mode is given in which the case includes a fixing piece that is used for attachment to an engine.

The above-described mode has excellent attachment workability since the connector-equipped case is easily fixed to the engine.

(12) As one example of the connector-equipped case of the present disclosure, a mode is given in which the connector-equipped case is attached directly above the engine.

In the above-described mode, the length of the wire harness that is connected to the connector portion can be shortened. Accordingly, the above-described mode contributes to the reduction of the size and weight of the engine control unit including the wire harness.

(13) As one example of the connector-equipped case of the present disclosure, a mode is given in which a circuit board connected to ends on one side of the terminals performs control of at least one of fuel injection of the engine and ignition of the engine.

An injector that performs fuel injection for an engine and a spark plug of an engine are typically provided above the engine. For this reason, in the above-described mode, in particular, it is possible to reduce the length of the wire harness by arranging the connector-equipped case directly above the engine. Accordingly, the above-described mode contributes to the reduction of the size and weight of the engine control unit including the wire harness.

(14) As one example of the connector-equipped case according to any one of (11) to (13) above, a mode is given in which the engine is an engine of an automobile.

In the above-described mode, the length of the wire harness can be reduced due to the connector-equipped case being arranged at a location near the engine, such as a location directly above the engine, as described above.

Accordingly, in the above-described mode, an engine control unit that is smaller and lighter in weight than the conventional structure can be constructed in a state including the wire harness. This mode contributes to an improvement in fuel efficiency.

(15) A connector-equipped wire harness according to an aspect of the present disclosure includes:

the connector-equipped case according to any one of (1) to (14) above; and

a wire harness connected to the end portions of the terminals.

The overall length of the wire harness is less than 800 mm.

Since the overall length of the wire harness is less than 800 mm, which is short, the connector-equipped wire harness of the present disclosure may be used arranged at a location near the engine, such as a location directly above the engine. Since the connector-equipped wire harness of the present disclosure includes the above-described connector-equipped case of the present disclosure, cracks are not likely to occur in the connector portion, and in particular, in the hood portion, even if the connector-equipped wire harness is arranged near an engine.

(16) An engine control unit (ECU) according to an aspect of the present disclosure includes:

the connector-equipped case according to any one of (1) to (14) above or the connector-equipped wire harness according to (15) above; and the circuit board that is stored in the case and is connected to the ends on one side of the terminals.

Since the ECU of the present disclosure includes the connector-equipped case of the present disclosure or the connector-equipped wire harness of the present disclosure, cracks are not likely to occur in the connector portion, and in particular, in the hood portion, even if the ECU is arranged at a location near an engine, such as a location directly above an engine. Also, since the wire harness can be shortened, or the wire harness is short, the ECU of the present disclosure is smaller and more lightweight than the above-described conventional structure.

### Detailed Embodiments of the Present Disclosure

Hereinafter, embodiments of the present disclosure will be described specifically with reference to the drawings. Identical reference numerals in the drawings indicate items with identical names.

### 1. Embodiments

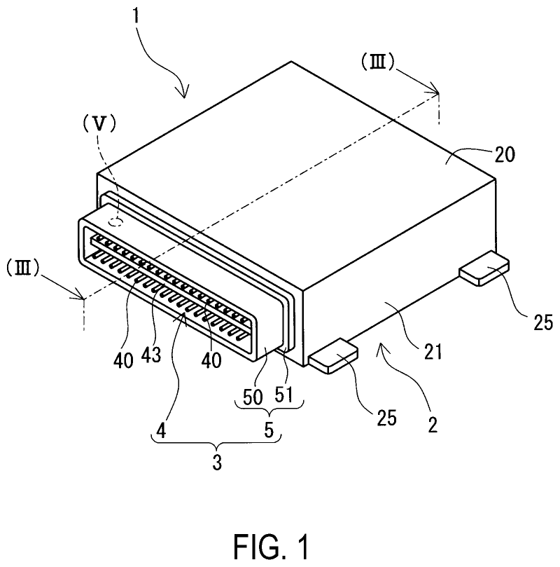

Structures of a connector-equipped case 1, a connector-equipped wire harness 10, and an engine control unit (ECU) 17 of an embodiment will be described mainly with reference to FIGS. 1 to 4. Thereafter, the materials of the constituent components of the connector-equipped case 1 of the embodiment will be described in detail.

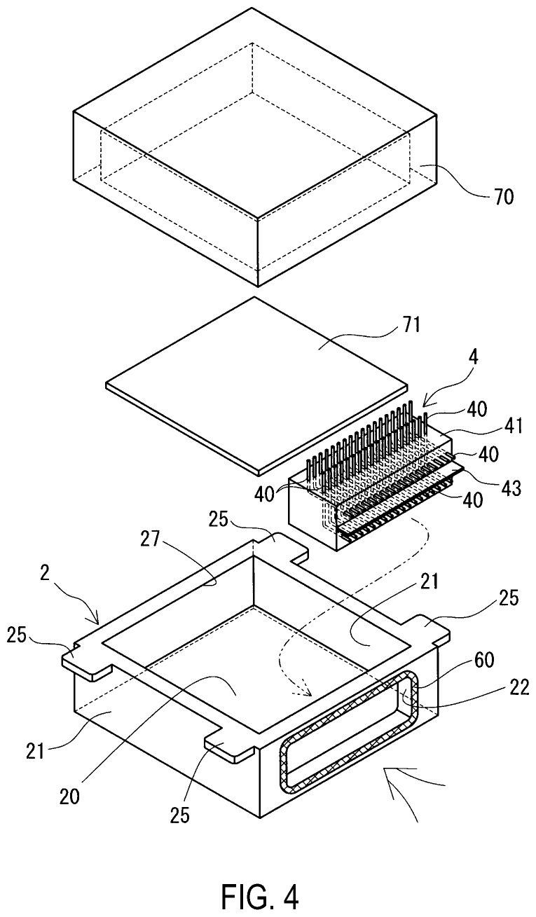

FIGS. 1 to 3 show a state in which a case 2 is arranged such that an opening portion 27 of the case 2 faces downward. FIG. 4 shows a state in which the case 2 is arranged such that the opening portion 27 of the case 2 faces upward.

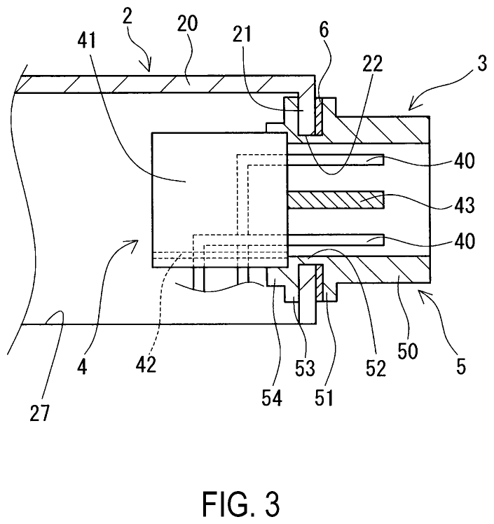

FIG. 3 mainly shows cross-sections of the case 2 and the hood portion 5, and shows the external appearance of a main body portion 41 of the core portion 4.

1-1. Overview

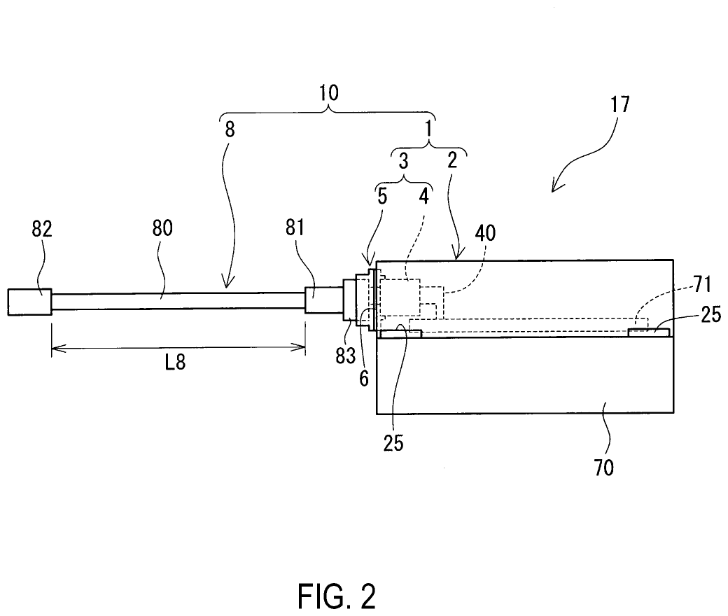

The connector-equipped case 1 of the embodiment includes the case 2 and a connector portion 3 (connector) that is fixed to the case 2 (FIG. 1). The case 2 is a container-shaped member having the opening 27 (FIG. 4), and is made of metal. The cover 70 is attached so as to cover the opening portion 27 of the case 2 (FIGS. 2 and 4). A circuit board 71 is stored in an internal space of the case 2 and the cover 70 (FIG. 2). The connector portion 3 includes multiple terminals 40. These terminals 40 electrically connect the circuit board 71 in the case 2 and an external device (e.g., the wire harness 8) outside of the case 2 to each other. The circuit board 71 includes a circuit that controls an electronic device such as the engine, for example. This connector-equipped case 1 stores the cover 70 and the circuit board 71 as described above, and is used as a constituent component of a control unit such as the ECU 17.

The connector-equipped case 1 of the embodiment differs from the above-described conventional structure in which the connector is interposed between the case and the cover. Specifically, the case 2 has a through hole 22 (FIGS. 3 and 4). The connector portion 3 is inserted through the through hole 22 of the case 2 (FIGS. 2 and 3). Also, the connector unit 3 includes a portion arranged inside of the case 2 and a portion arranged outside of the case 2. Both portions are supported in one piece by the case 2 (FIGS. 2 and 3). Specifically, the connector portion 3 includes a core portion 4 (core) and a hood portion 5 (hood). The core portion 4 is a resin molded body that supports the multiple terminals 40 (see also FIG. 4). The core portion 4 is arranged mainly in the case 2. The hood portion 5 is a resin molded body formed by molding the region around the through hole 22 of the case 2 and a portion of the core portion 4 in one piece (FIG. 3). The hood portion 5 is mainly arranged outside of the case 2. The “region around the through hole 22 of the case 2” in this context includes the peripheral edge of the through hole 22 on the outer peripheral surface of the case 2 and a ring-shaped region surrounding the peripheral edge (see the region denoted by cross-hatching in FIG. 4), the inner peripheral space of the through hole 22, the peripheral edge of the through hole 22 on the inner peripheral surface of the case 2, and a ring-shaped region including the peripheral edge.

In particular, with the connector-equipped case 1 of the embodiment, the constituent material of the hood portion 5 is a resin composition containing polybutylene terephthalate (PBT) and polyethylene terephthalate (PET). Even if the above-described specific resin composition is repeatedly subjected to a heat cycle in a state of being provided in contact with a metal, cracks are not likely to occur therein. The connector-equipped case 1 of the embodiment, in which the hood portion 5 composed of this specific resin composition is provided in contact with the case 2 composed of a metal such as an aluminum-based alloy, can be used attached in a usage environment that is repeatedly subjected to a heat cycle, such as a location near an engine, for example, a location directly above an engine.

1-2. Connector-Equipped Case

1-2-1. Case

As illustrated in FIG. 4, examples of the case 2 include a box-shaped container that includes a bottom portion 20 and a frame-shaped side wall 21 that is provided in a standing manner on the bottom portion 20, the side of the container opposing the bottom portion 20 being open. The inner space of the case 2 is used as a storage space for predetermined stored items, such as a portion of the connector portion 3 (a portion of the hood portion 5 and the core portion 4) and the circuit board 71 here. Although a cuboid case 2 is illustrated in FIG. 1, the shape and size of the case 2 and the shape and size of the later-described cover 70 may be adjusted according to the shape and size of the above-described stored objects.

In a portion of the side wall 21, the case 2 includes a through hole 22 that passes through the case 2. Due to the inner circumferential surface of the through hole 22 holding the intermediate portion of the connector portion 3 (FIG. 3), one end portion of the connector portion 3 is stored in the case 2 and the other end portion of the connector portion 3 is exposed (protrudes) to the outside of the case 2.

The shape, size, and number of the through hole 22 may be adjusted according to the shape, size, and number of the connector portion 3. Although the case 2 of the present example includes one rectangular through hole 22, the case 2 may also include multiple through holes 22.

In addition, if the case 2 includes a fixing piece 25 that is used for attachment to an installation target, it is easier to perform fixing to the installation target, and excellent attachment workability is achieved. Examples of the above-described installation target typically include an engine, such as an engine of an automobile. FIG. 4 illustrates a case in which tongue-shaped members that protrude outward from the four corners of the cuboid case 2 are fixing pieces 25. The shape, size, number, forming positions, and the like of the fixing pieces 25 can be changed as appropriate.

Examples of the case 2 include a die-cast member. If die casting is used, the box-shaped case 2 that is formed due to the bottom portion 20 and the side wall 21 being molded in one piece can be easily manufactured. The connector-equipped case 1 has excellent manufacturability due to the box-shaped case 2 being easy to manufacture. Also, if the bottom portion 20 and the side wall 21 are an integrally-molded member, the case 2 also has excellent sealability. If the later-described cover 70 is also a die-cast member, the cover 70 can also be manufactured easily and has excellent sealability. Note that the case 2 and the cover 70 may also be a member other than a die-cast member (e.g., a plastic processed member subjected to deep drawing or the like).

1-2-2. Cover

Examples of the cover 70 typically include a box-shaped container, similarly to the case 2. Note that with the connector-equipped case 1 and the connector-equipped wire harness 10 of the embodiment, in a state prior to storing the circuit board 71, the cover 70 is not included, and the case 2 is open.

The case 2 and the cover 70 are easily attached when flange portions (not shown) that are extended outward from the opening edges are included therein. If an adhesive (not shown) is interposed between the flange portion of the case 2 and the flange portion of the cover 70, the sealability is improved.

1-2-3. Connector Portion

1-2-3-1. Terminals

The terminals 40 are typically rod-shaped (pin-shaped) members constituted by a conductive material such as copper or a copper alloy. The terminals 40 include connection ends (ends on one side) for connecting with the circuit board 71, and connection ends (ends on another side) for connecting with an external device. As illustrated in FIG. 4, the multiple terminals 40 are arranged side by side on one line at a predetermined interval, and this group of terminals is further aligned in multiple levels. Also, the terminals 40 are bent as appropriate such that the end portions face a predetermined direction. The multiple terminals 40 are supported by the core portion 4 (main body portion 41) such that the above-described aligned and bent state is maintained and connection to the circuit board 71 and the external device is possible. The number, alignment, bent state, and the like of the terminals 40 can be changed as appropriate.

In the connector-equipped case 1, the connection ends (ends on the one side) of the terminals 40 that are connected to the circuit board 71 are arranged inside of the case 2. The connection ends (ends on the other side) of the terminals 40 that are connected to the external device are arranged so as to face the outside of the case 2 via the through hole 22 of the case 2. Typically, as shown in FIGS. 1 and 3, the intermediate portions of the terminals 40 are inserted through the through hole 22 and the ends on the other sides of the terminals 40 are arranged outside of the case 2.

1-2-3-2. Core Portion

The core portion 4 is a member that holds the intermediate portions of the multiple terminals 40 and supports the end portions on both sides of the terminals 40 in an exposed state (FIGS. 3 and 4). The core portion 4 of the present example includes a support plate 42 (FIG. 3) to which the terminals 40 are fixed through press-fitting, a main body portion 41, and a partition portion 43. The main body portion 41 is a member that supports at least a portion of the peripheral edge portion of the support plate 42. Due to the main body portion 41 being arranged at a predetermined position on the case 2, the end portions of the terminals 40 held in the support plate 42 are arranged in a predetermined orientation. FIG. 3 illustrates a state in which the support plate 42 is arranged in the case 2 such that the front and rear surfaces of the support plate 42 are parallel with the axial direction of the through hole 22. Note that in FIGS. 2 and 4, the main body portion 41 and the support plate 42 are simplified and are indicated by cuboids. The partition portion 43 is a flat plate-shaped member that protrudes from the outer circumferential surface of the main body portion 41. The partition portion 43 is interposed between adjacent terminal groups (FIG. 1) and increases the electrical insulation between the terminal groups. For example, the core portion 4 is manufactured by being injection-molded (insert-molded) in the plate member to which the above-described terminals 40 are fixed.

The shape, size, and the like of the core portion 4 may be adjusted as appropriate according to the number, alignment state, and the like of the terminals 40. Also, although a case is indicated in which the connector-equipped case 1 of the present example includes one core portion 4, the connector-equipped case 1 may also include multiple core portions 4.

1-2-3-3. Hood Portion

The hood portion 5 is a member that is integrated with the core portion 4 and forms the connector portion 3 along with the core portion 4. The hood portion 5 includes a portion arranged outside of the case 2. The portion of the hood portion 5 that is arranged outside of the case 2 has a function of improving sealability by coming into areal contact with the case 2, a function of mechanically protecting the connection ends of the multiple terminals 40 that are connected to the external device, a function of guiding the external device to the connection ends when the terminals 40 and the external device are connected, and the like. The hood portion 5 is, for example, manufactured by performing injection molding (insert molding) in the case 2 and the core member 4.

The hood portion 5 of the present example is an integrally molded object that includes a main body portion 50, an outer flange portion 51, an insertion portion 52, an inner flange portion 53, and a joining portion 54 (FIG. 3), and in which these portions are continuous with each other. Also, the hood portion 5 of the present example is an overall tube-shaped member that conforms to the inner peripheral shape of the through hole 22 (FIG. 1). The main body portion 50 and the outer flange portion 51 are arranged outside of the case 2 (FIGS. 1 and 3). The insertion portion 52 is arranged in contact with the inner peripheral surface of the through hole 22 (FIG. 3). The inner flange portion 53 and the joining portion 54 are arranged inside of the case 2 (FIG. 3).

The main body portion 50 of the present example is a tube-shaped portion that surrounds the connection ends of the terminals 40 that are connected to the external device. The main body portion 50 is provided so as to protrude in the axial direction of the through hole 22 from a ring-shaped region that surrounds the peripheral edge of the through hole 22 on the outer peripheral surface of the case 2. The main body portion 50 contributes to mechanical protection and protection from the environment of the end portions of the above-described terminals 40, improvement in electrical insulation between the surrounding member and the terminals 40 in the case where the connector-equipped case 1 is installed, improvement in the connection workability of the external device, and the like.

The outer flange portion 51 is a ring-shaped portion that is extended in a direction intersecting the axial direction of the main body portion 50 (substantially matches the axial direction of the through holes 22 in the present example) from the peripheral edge of the main body portion 50. The outer flange portion 51 is arranged in contact with the ring-shaped region surrounding the peripheral edge of the through holes 22 on the outer peripheral surface of the case 2. The hood portion 5 including the outer flange portion 51 can increase the bonding area between the case 2 and the adhesive layer 6 and can be favorably integrated with the case 2. The sealability is also improved due to the increase in the surface area of the hood portion 5. The size of the outer flange portion 51 and the size of the later-described inner flange portion 53 may be adjusted according to the size of the through hole 22.

The insertion portion 52 is provided so as to fill in the region on the inner peripheral surface side of the inner peripheral space of the through hole 22. Also, the insertion portion 52 integrates the portion of the hood portion 5 that is arranged outside of the case 2, and the portion of the hood portion 5 that is located inside of the case 2. In the present example, an inner space is formed in which three portions, namely the insertion portion 52, the above-described outer flange portion 51, and the main body portion 50 are continuous with each other. The thicknesses and the like of the above-described three portions are adjusted such that the above-described inner space has a uniform size in the axial direction of the main body portion 50, the size being such that no contact is made with the terminals 40 (FIG. 3).

The inner flange portion 53 is a ring-shaped portion that is extended in a direction perpendicular to the axial direction of the main body portion 50 from the peripheral edge of the insertion portion 52. The inner flange portion 53 is arranged in contact with a ring-shaped region surrounding the peripheral edge of the through hole 22 on the inner peripheral surface of the case 2. Also, the inner flange portion 53 and the above-described outer flange portion 51 are provided so as to sandwich the side wall 21 of the case 2 (FIG. 3). Due to this, the hood portion 5 can be strongly integrated with the case 2, and the sealability is also further improved.

The joining portion 54 is a portion that integrates the core portion 4 and the hood portion 5 (FIG. 3). The joining portion 54 of the present example is provided in a ring shape so as to cover a location that is a portion of the core portion 4 and does not interfere with the terminals 40. The shape and size of the joining portion 54 may be adjusted as appropriate according to the shape and size of the core portion 4.

1-2-4. Adhesive Layer

The connector-equipped case of the present example includes an adhesive layer 6 between the case 2 and the hood portion 5 of the connector portion 3 (FIGS. 2 and 3). The adhesion layer 6 improves the bondability with the case 2 and the hood portion 5 and improves the sealability as well. Since the hood portion 5 is constituted by the above-described specific resin composition and has excellent bondability with the adhesive layer 6, the above-described bondability and sealability are improved. The connector-equipped case 1 of the present example includes the adhesive layer 6 between a ring-shaped region surrounding the peripheral edge of the through hole 22 on the outer peripheral surface of the case 2 (refer to the region indicated by cross-hatching in FIG. 4) and the outer flange portion 51.

1-3. Connector-Equipped Wire Harness

The connector-equipped wire harness 10 of the embodiment includes: a connector-equipped case 1 of the embodiment and a wire harness 8 that is connected to the end portions (ends on the other side) of the terminals 40 of the connector portion 3 (FIG. 2). The ends on one side of the terminals 40 are connected to the circuit board 71. One end of the wire harness 8 is electrically connected to the circuit board 71 via the terminals 40. The other end of the wire harness 8 is electrically connected to the electronic device controlled by the circuit board 71.

1-3-1. Wire Harness

The wire harness 8 includes: one or more wires 80; and connectors 81 and 82 that are attached to the end portions of the wires 80. The wires 80 include conductors and electrical insulation layers. The conductors are typically constituted by a conductive material such as copper, aluminum, or an alloy thereof. The electrical insulation layer is constituted by an electrical insulating material such as resin and covers the external periphery of the conductor. FIG. 2 illustrates a case in which one wire 80 is included, but the wire harness 8 may also include multiple wires 80. An appropriate male connector or female connector can be used as the connectors 81 and 82.

As illustrated in FIG. 2, the connector 83 (e.g., female connector) may also separately be interposed between the connector 81 (e.g., a male connector) of the wire harness 8 and a connector portion 3 (e.g., a male connector) of the connector-equipped case 1.

The overall length L8 (here, the overall length of the wire 80 excluding the connectors 81 and 82) of the wire harness 8 may be adjusted as appropriate according to the distance from the circuit board 71 to the electronic device. Examples of the connector-equipped wire harness 10 include a mode in which the overall length L8 of the wire harness 8 is less than 800 mm. The shorter the above-described overall length L8 is, the smaller the size and the lighter the weight of the ECU 17 including the wire harness 8 can be made. For this reason, the above-described overall length L8 may be 700 mm or less, or furthermore 500 mm or less, 300 mm or less, or 250 mm or less.

The mode in which the above-described overall length L8 is less than 800 mm can be used when the distance from the circuit board 71 to the electronic device is short. For example, if the circuit board 71 controls the electronic device of the engine, the connector-equipped wire harness 10 is arranged at a location near the engine, such as a location directly above the engine. In this case, the circuit board 71 can control an electronic device provided above the engine, such as an injector coil for performing fuel injection, a spark plug, and the like.

1-4. Engine Control Unit (ECU)

The ECU 17 of the embodiment includes: the connector-equipped case 1 of the embodiment or the connector-equipped wire harness 10 of the embodiment, and the circuit board 71 that is stored in the case 2 and is connected to the ends on one side of the terminals 40 (FIG. 2). Typically, the ECU 17 includes the cover 70 and stores the circuit board 71 with the case 2 and the cover 70. The circuit board 71 is connected to the electronic device of the engine via the wire harness 8 connected to the ends on the other side of the terminals 40. Due to this connection, the above-described electronic device performs predetermined control using the circuit board 71.

If the circuit board 71 performs control of at least one of the fuel injection of the engine and the ignition of the engine, the ECU 17 can be arranged directly above the engine, as described above. In this case, the overall length L8 of the wire harness 8 can be made shorter.

1-5. Constituent Materials

1-5-1. Resin Composition

The resin composition constituting the hood portion 5 contains PBT and PET. PBT and PET are polyethylene-based thermoplastic resins. For this reason, if the above-described resin composition is injection-molded, the hood portion 5 can be easily manufactured. In particular, due to the above-described resin composition containing PET in addition to PBT, it has excellent toughness compared to the conventional constituent material of the connector (e.g., PBT). For this reason, it is thought that cracks are less likely to occur even in a usage environment in which the above-described resin composition is provided in contact with a metal such as an aluminum-based alloy and is repeatedly subjected to a heat cycle. It is thought that when cracks occur, the cracks are not likely to develop, even in a usage environment that is repeatedly subjected to vibration in addition to a heat cycle. Also, the above-described resin composition is not likely to warp, even if provided in contact with the above-described metal. For this reason, the above-described resin composition is not likely to separate from the metal, and the state in which the above-described resin composition is integrated with the metal is likely to be maintained. Even if the hood portion 5 composed of this specific resin composition is arranged in the above-described usage environment, such as a location near an engine, it is expected that cracks will not be likely to occur, and the state of being in areal contact with the case 2 made of metal can be favorably maintained.

1-5-1-1. PBT Content

The above-described resin composition may contain the maximum amount of PBT, that is, the above-described resin composition may mainly contain PBT. The resin composition that mainly contains PBT has an excellent injection molding property. The hood portion 5 and the like composed of this resin composition have excellent manufacturability.

Quantitatively, the content of the PBT in the above-described resin composition may be 150 parts by mass or more and 400 parts by mass or less, with respect to 100 parts by mass of PET.

If the PBT content is 150 parts by mass or more in proportion to PET, cracks are not likely to occur in the hood portion 5 due to an improvement in toughness resulting from the inclusion of PET. Also, the hood portion 5 is not likely to warp, and has excellent adhesion to the case 2. For example, even if the case 2 and the connector portion 3 are not fastened by bolts, the state in which the case 2 and the connector portion 3 are integrated is favorably maintained. Since bolt-fastening is not needed, the connector-equipped case 1 has excellent manufacturability. If the PBT content is 400 parts by mass or less in proportion to the PET, effects such as reducing the occurrence of cracks due to the inclusion of PET are obtained, and a favorable injection molding property resulting from mainly containing PBT is also obtained.

If the PBT content is 180 parts by mass or more, or furthermore 200 parts by mass or more, the effect of reducing the occurrence of cracks is more likely to be obtained. If the PBT content is 350 parts by mass or less, or furthermore 320 parts by mass or less, or 300 parts by mass or less, a favorable injection molding property is likely to be obtained.

1-5-1-2. Other Additives

The above-described resin composition may also further include a filler. Examples of the filler include at least one of glass fibers and glass flakes. The glass fibers are elongated needle-like glass materials. The resin composition containing glass fibers is likely to have improved strength. Glass flakes are scale-like glass materials. The resin composition containing the glass flakes is likely to have reduced anisotropy relating to thermal expansion and contraction. As a result, the hood portion 5 is not likely to warp.

The content of the above-described filler may be, for example, 20 parts by mass or more and 60 parts by mass or less, with respect to 100 parts by mass of the above-described resin composition. If the content is 20 parts by mass or more, effects such as improving strength and reducing warping are likely to be obtained. If the content is 60 parts by mass or less, a reduction of the injection molding property and the like resulting from excessive inclusion of the filler are likely to be suppressed. If the content is 25 parts by mass or more, or furthermore 30 parts by mass or more, further improvement of the strength and further reduction of warping can be expected. If the content is 55 parts by mass or less, or furthermore 50 parts by mass or less, a favorable injection molding property is likely to be obtained.

The above-described resin composition may also contain both the glass fibers and the glass flakes. In this case, the hood portion has high strength and is not likely to warp. Also, in this case, the amount of glass fibers may be greater than the amount of glass flakes. The mass ratio of the glass fibers and the glass flakes may be, for example, glass fibers:glass flakes=6 to 8:4 to 2. Due to the amount of glass fibers being relatively larger, it is easy to prevent the glass flakes from being distributed unevenly in the resin composition, and the glass flakes are likely to be distributed evenly.

The above-described resin composition may also further contain an elastomer. The elastomer contributed to an improvement in the toughness of the resin composition. As a result, cracks will be even less likely to occur in the hood portion, and the hood portion 5 will be less likely to warp. The content of the elastomer may be 1 part by mass or more and 50 parts by mass or less, with respect to 100 parts by mass of the above-described resin composition.

In addition, the above-described resin composition may also contain an additive that improves hydrolysis resistance. Examples of this kind of additive include epoxy resin and carboxyimide. The content of the epoxy resin and the like may be 1 part by mass or more and 20 parts by mass or less, with respect to 100 parts by mass of the above-described resin composition.

1-5-1-3. Structure

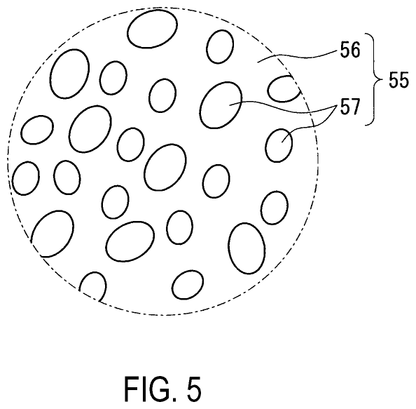

The phase structure of the above-described resin composition may be a sea-island structure as illustrated in FIG. 5. In particular, a sea portion 56 of the sea-island structure in the resin composition 55 may mainly contain PBT, and island portions 57 of the sea-island structure may mainly contain PET. Here, the “sea portion 56 mainly containing PBT” means that with the constituent components of the sea portion 56 being 100 mass %, PBT makes up 80 mass % or more of the sea portion 56. The “island portions 57 mainly containing PET” in this context means that with respect to 100 mass % of the constituent components of the island portions 57, PET makes up 80 mass % or more of the island portions 57. With the sea-island structure in which the sea portion 56 mainly contains PBT and the island portions 57 mainly contain PET, it can be said that the PET (island portions 57) has been evenly dispersed in the PBT (sea portion 56). This resin composition 55 has a favorable injection molding property due to mainly containing PBT, and an effect of reducing the occurrence of cracks and an effect of reducing warping are likely to be obtained as a result of including PET. Cracks are even less likely to occur in the hood portion 5 composed of the resin composition 55 having this sea-island structure, and the hood portion 5 is even less likely to warp. In the above-described sea-island structure, for example, the melted resin composition may be sufficiently mixed such that the PET is evenly dispersed in the PBT in the manufacturing process. Note that the phase structure of the above-described resin composition may also be a bicontinuous structure.

1-5-1-4. Other Applications

The specific resin composition containing PBT and PET can also be used as the constituent material of the core portion 4. If the constituent material of the core portion 4 and the constituent material of the hood portion 5 are substantially the same, the state in which both the core portion 4 and the hood portion 5 are integrated is favorably maintained. This is because in both the core portion 4 and the hood portion 5, properties such as the thermal expansion coefficient are substantially equal, and therefore the thermal expansion states are likely to be equal even if subjected to a heat cycle. Also, if the hood portion 5 is manufactured through injection molding, both the core portion 4 and the hood portion 5 are favorably bonded using the heat obtained during injection molding, or the like. Due to this reason as well, the state in which both the core portion 4 and the hood portion 5 are integrated is favorably maintained. Furthermore, during injection molding, the molding of the hood portion 5 and the integration of the hood portion 5 and the core portion 4 can be performed simultaneously. In this respect, this mode also has excellent manufacturability. Note that the constituent material of the core portion 4 may also be a constituent material other than the above-described specific resin composition. The constituent material of the core portion 4 may also be, for example, a resin composition that mainly contains PBT and does not contain PET.

1-5-2. Case

The constituent material of the case 2 is a metal, for example. An aluminum-based alloy (hereinafter called an Al-based alloy) is an example of a metal. The “Al-based alloy” in this context refers to an alloy that contains additional elements, the remaining portion being composed of Al and inevitable impurities, with the Al-based alloy being set to 100 mass %. The content of Al is more than 50 mass %, or furthermore 60 mass % or more, or 70 mass % or more. The Al-based alloy is lighter in weight compared to an iron-based alloy or the like. For this reason, the case 2 composed of the Al-based alloy is lightweight and contributes to reducing the weight of the connector-equipped case 1. Also, the Al-based alloy has excellent thermal conductivity compared to an iron-based alloy or the like. For this reason, the case 2 composed of the Al-based alloy has excellent thermal conductivity. The connector portion 3 provided in contact with this case 2 easily dissipates heat to the case 2 and is not likely to trap heat. Accordingly, it is expected that the connector-equipped case 1 including the case 2 composed of the Al-based alloy will be able to mitigate thermal shock accompanying a heat cycle during use, and the occurrence of cracks in the hood portion 5 will be more easily reduced. A known composition can be used as the Al-based alloy.

Examples of the Al-based alloy include an Al-based alloy that contains Si (silicon) in an amount of 1 mass % or more and 30 mass % or less as an additional element. Also, the Al-based alloy containing Si in the above-described range has excellent castability (mold-release property), and therefore the case 2 is easily manufactured through die casting. The connector-equipped case 1 has more excellent manufacturability due to the case 2 being easy to manufacture. Examples of the Al-based alloy containing Si in the above-described range include ADC1, ADC3, ADC10, ADC12, and ADC14, which are defined in JIS H 5302 (2006).

Here, the die-cast member composed of the Al-based alloy containing Si in the above-described range generally includes a chill layer (not shown) on its surface. The chill layer improves the mold-release property. However, if the resin is injection-molded in a die-cast member having the chill layer, the above-described die-cast member and the resin molded body are not likely to stick to each other. For this reason, if the resin is injection-molded in the above-described die-cast member, it is desirable to implement surface processing (e.g., blast processing) for removing the chill layer. In contrast to this, the above-described specific resin composition that contains PBT and PET is not likely to warp as described above, and therefore the resin composition is likely to stick to even the above-described die-cast member. Accordingly, even if the constituent material of the case 2 is an Al-based alloy containing Si in the above-described range, the case 2 has excellent adhesion to the hood portion 5 composed of the above-described specific resin composition. If the adhesive layer 6 is included between the case 2 and the hood portion 5, the case 2 and the hood portion 5 are more favorably bonded to each other. Depending on the material of the adhesive layer 6, the above-described surface processing is not needed. As a result of omitting the above-described surface processing, the connector-equipped case 1 has more excellent manufacturability.

1-5-3. Adhesive Layer

Examples of the constituent material of the adhesive layer 6 include a thermosetting adhesive. In particular, if the constituent material of the adhesive layer 6 can be cured using the pressure and heat obtained during injection molding, formation of the hood portion 5, curing of the adhesive layer 6, and bonding of the case 2 and the hood portion 5 can be performed simultaneously during injection molding. In this case, there is a smaller number of steps, and thus the connector-equipped case 1 has more excellent manufacturability.

Examples of the adhesive that can be cured using the pressure and heat obtained during injection molding include: an adhesive containing non-diene-based rubber, an adhesive containing non-diene-based rubber and an amino silane coupling agent, and an adhesive containing acrylic rubber.

“Non-diene-based rubber” in this context is rubber that does not contain a carbon-carbon double bond in a main chain. Examples of the non-diene-based rubber include an O-group rubber in the rubber classification of JIS K 6397 (2005). An O-group rubber is a rubber that has carbon and oxygen in a main chain. Specific examples of non-diene-based rubber include: epichlorohydrin rubber, butyl rubber, ethylene propylene rubber, urethane rubber, silicone rubber, chlorosulfonated rubber, chlorinated polyethylene, acrylic rubber, and fluororubber. Examples of epichlorohydrin rubber include a homopolymer of epichlorohydrin, and a rubber-like copolymer of ethylene oxide and epichlorohydrin, and either of these may be used. Examples of an O-group rubber other than epichlorohydrin rubber include: a rubber-like copolymer of ethylene oxide and epichlorohydrin, a rubber-like copolymer of ethylene oxide, epichlorohydrin, and allyl glycidyl ether, and a rubber-like copolymer of epichlorohydrin and allyl glycidyl ether. In addition, an adhesive made of a commercially-available non-diene-based rubber may also be included.

The adhesive containing non-diene-based rubber and an amino silane coupling agent and the adhesive containing acrylic rubber have excellent adherability with the case 2 and with the hood portion 5. As a result, the above-described adhesive can favorably bond the case 2 and the hood portion 5 and has improved sealability. Furthermore, if the constituent material of the case 2 is an Al-based alloy containing Si in the above-described range, the above-described adhesive can strongly bond to the case 2 and the hood portion 5 without performing the above-described surface processing. Due to there being no need to remove the chill layer, the connector-equipped case 1 has more excellent manufacturability.

The content of the non-diene-based rubber may be, for example, 50 mass % or more and 80 mass % or less with respect to 100 mass % of the adhesive. The content of the amino silane coupling agent may be, for example, 0.5 mass % or more and 2 mass % or less with respect to 100 mass % of the adhesive. The adhesive with the content in the above-described range suitably contains the amino silane coupling agent, and therefore can favorably bond the case 2 and the hood portion 5. The glass-transition temperature of the adhesive containing acrylic rubber is, for example, greater than −20° C. and less than 38° C. The adhesive with the glass-transition temperature in the above-described range suitably includes the acrylic rubber, and therefore can favorably bond the case 2 and the hood portion 5.

The thickness of the adhesive layer 6 is, for example, 0.1 mm or more and 0.5 mm or less. If the thickness is in the above-described range, the bonded state of the case 2 and the hood portion 5 is favorably maintained, and the sealability is improved by the adhesive layer 6.

### 2. Manufacturing Method

In the connector-equipped case 1 of the embodiment, the hood portion 5 and the core portion 4 need only be manufactured in a stepwise manner. For example, the connector-equipped case 1 may be manufactured using a manufacturing method including the following steps (see FIG. 4).

First Step

The case 2 including the through hole 22, and the core portion 4 supporting the multiple terminals 40 are prepared.

Second Step

The resin composition is injection-molded in the region around the through hole 22 of the above-described case 2 in a state in which the core portion 4 is arranged in the internal space of the case 2 such that the end portions of the terminals 40 face outward of the case 2 via the through hole 22 of the case 2, and thus the hood portion 5 is formed, and a portion of the core portion 4 and the hood portion 5 are integrated.

The resin composition contains PBT and PET. Please refer to the section “Resin Composition” above for the details of the resin composition.

If the adhesive layer 6 is included, the above-described manufacturing method need only include a step of forming an adhesive layer 60 in the region around the through hole 22 on the outer peripheral surface of the case 2, prior to the above-described “Second Step”. Note that for ease of comprehension, the adhesive layer 60 is indicated by cross-hatching in FIG. 4.

Hereinafter, the steps will be described simply.

In the first step described above, the case 2 is manufactured using die casting, as described above. The core portion 4 is manufactured by performing injection molding (insert molding) on a member that supports the multiple terminals 40 in a predetermined aligned and bent state as described above.

In the step of forming the above-described adhesive layer 60, the half-cured adhesive layer 60 is formed. For example, after the melted adhesive is applied to the above-described region around the through hole 22 or a sheet member is arranged in the above-described region, the adhesive may be heated and put in a half-cured state.

In the above-described “second step”, for example, the resin composition is injection-molded from outside of the case 2 on the outer peripheral surface of the case 2 to form the main body portion 50 and the outer flange portion 51 of the hood portion 5 outside of the case 2. For example, the resin composition is also injected from the outside of the case 2 into the case 2 through the through hole 22 of the case 2 to form the insertion portion 52, the inner flange portion 53, and the joining portion 54. The core portion 4 and the hood portion 5 are integrated by forming the joining portion 54. Furthermore, for example, by continuously injecting the resin composition from the outside of the case 2 into the case 2 through the through hole 22, an integrally molded object that is continuous from the main body portion 50 to the joining portion 54 is molded. Prior to the injection molding, the case 2 may also be pre-heated to about the same temperature as the mold for molding, for example. In this case, the fluidity of the resin is improved and the hood portion 5 is favorably molded. Heating for putting the above-described adhesive in a half-cured state may also be used in pre-heating.

If the adhesive constituting the adhesive layer 60 can be cured using the pressure and heat obtained during injection molding as described above, the curing of the adhesive layer 6 and the bonding of the case 2 and the hood portion 5 by the adhesion layer 6 can be performed at the same time as the formation of the hood portion 5.

2-1. Main Effects

The connector-equipped case 1 and the connector-equipped wire harness 10 of the embodiment include the hood portion 5 composed of a resin composition containing PBT and PET. For this reason, cracks are not likely to occur in the connector portion 3, and in particular, in the hood portion 5, even in a usage environment that is repeatedly subjected to a heat cycle, and furthermore, vibration. Also, even if cracks occur, the cracks are not likely to develop. Accordingly, the connector-equipped case 1 and the connector-equipped wire harness 10 of the embodiment can be arranged at a location near an engine, such as a location directly above an engine. When arranged directly above the engine or the like, the entire length L8 of the wire harness 8 can be reduced (e.g., less than 800 mm). As a result, the ECU 17 including the wire harness 8 is compact and lightweight. If the connector-equipped case 1, the connector-equipped wire harness 10, and the ECU 17 are installed on the engine of an automobile, the compact and lightweight ECU 17 contributes to an improvement in fuel efficiency.

### 3. Test Example 1

Samples obtained by injection-molding resin compositions of various compositions in metal members were produced, thermal shock tests were performed, and the state of the occurrence of cracks in the resin compositions was examined.

3-1. Production of Samples

A metal member in this context is a 50 mm×50 mm×30 mm cuboid member composed of iron. The resin compositions shown in Table 1 are injection-molded (insert-molded) so as to cover the surfaces of the above-described metal members, and thus the resin molded bodies are produced. The thickness of a resin molded body is 1.5 mm. Before the injection molding, surface processing is not performed on the metal members. Also, the metal members are not provided with adhesive layers.

The resin composition of sample No. 1 contains PBT and PET. The content of the PBT is 233 parts by mass with respect to 100 parts by mass of PET. Also, the resin composition of sample No. 1 contains glass fibers (indicated as “GF” in Table 1) and glass flakes (indicated as “GS” in Table 1) as fillers. The content of the fillers is 40 parts by mass with respect to 100 parts by mass of the resin composition. The mass ratio of the glass fibers and the glass flakes is glass fibers:glass flakes=6:4. Furthermore, the resin composition of sample No. 1 contains elastomer. The elastomer content is 10 parts by mass with respect to 100 parts by mass of the resin composition. The total content of PBT and PET is 50 parts by mass or more with respect to 100 parts by mass of the resin composition. In addition, the resin composition of sample No. 1 contains 5 parts by mass of epoxy resin with respect to 100 parts by mass of the resin composition as an additive for improving hydrolysis resistance. Note that the epoxy resin may also be omitted. After the resin composition of sample No. 1 is sufficiently mixed, the resin composition is sufficiently dried and injection molding is performed.

The resin compositions of samples No. 11 and No. 12 are commercially-available resin compositions containing PBT, and do not contain PET and elastomer.

The resin composition of sample No. 11 contains PBT and polycarbonate (PC), and contains glass fibers and glass flakes as fillers. The content of the fillers is 40 parts by mass. The resin composition of sample No. 11 does not contain epoxy resin.

The resin composition of sample No. 12 contains PBT and acrylonitrile styrene (AS) and contains only glass fibers as the filler. The content of the filler is 30 parts by mass. The resin composition of sample No. 12 contains epoxy resin. In Table 1 and Tables 2 and 3, which will be described later, the “k” mark means that the resin composition contains epoxy resin.

Common conditions that are used for injection molding of PBT or the like can be used as the conditions for injection molding of all of the resin compositions of the samples.

3-2. Thermal Shock Test

Multiple cycles in which the produced samples are held for 30 minutes at −40° C. and are thereafter held for 30 minutes at 125° C. are repeated. The produced samples were retrieved from the thermostatic oven each predetermined cycle, and the existence of cracks was checked visually at room temperature (here, about 20° C.). With this test, visual checking is performed at 100 cycles, 250 cycles, 500 cycles, 750 cycles, 1000 cycles, 1500 cycles, and 2000 cycles. If cracks are present, an evaluation of “B” is given, and if cracks are not present, an evaluation of “G” is given, and the evaluation results are shown in Table 1.

TABLE 1

| Sample No. | | 1 | 11 | 12 |
|---|---|---|---|---|
| Resin | Resin | PBT + PET | PBT + PC | PBT + AS |
| composition | Filler | GS + GF | GF + GS | GF |
| | Content | 40 | 40 | 30 |
| | (parts | | | |
| | by mass) | | | |
| | Elastomer | Present | Not present | Not present (*) |
| Number | 100 | G | B | B |
| of | 250 | G | — | — |
| cycles | 500 | G | — | — |
| | 1000 | G | — | — |
| | 2000 | G | — | — |

As shown in Table 1, no cracks occurred in the resin composition of sample No. 1, even though the thermal shock test was repeated for 2000 cycles. Note that in Table 1, the evaluation results for 750 cycles and 1500 cycles are omitted, but no cracks occurred in any of the cycles. Also, it was confirmed that no cracks occurred even when the number of cycles exceeded 2000 cycles. On the other hand, cracks occurred in samples No. 11 and No. 12 at 100 cycles.

The following is thought of as one reason why cracks occur. The thermal expansion coefficients of the metal and the resin are different. For this reason, when subjected to a heat cycle, stress caused by the above-described difference in thermal expansion coefficients is applied at a location of the injection-molded resin molded body that is in contact with the metal. It is thought that due to this thermal stress, cracks are likely to occur, originating at a portion of the resin molded body, in particular, at the welded portion, It is thought that the resin composition containing PET in addition to PBT has improved toughness due to the inclusion of PET, whereby the resin molded body of sample No. 1 reduced the occurrence of cracks even when repeatedly subjected to a heat cycle in a state of being provided in contact with the metal.

In this test, it is thought that since the resin composition contains a suitable amount of PET and furthermore contains elastomer, the resin molded body of sample No. 1 had further improved toughness and cracks were not likely to occur therein. Note that, for example, nuclear magnetic resonance spectrometry (NMR) may be used for component analysis of the resin molded body, such as measurement of the content of PBT, and determination of whether or not an elastomer is included. The composition of the resin molded body substantially maintains the composition of the resin composition using the raw material.

Furthermore, in this test, it is thought that the cracks were not likely to occur due to the fact that the resin composition of sample No. 1 is thought to have a sea-island structure including a sea portion that mainly contains PBT and island portions that mainly contain PET, and that the PET is evenly dispersed in the PBT. Note that an atomic force microscope (AFM), a transmission electron microscope (TEM), or the like may be used to check the phase structure of the resin molded body. For example, an energy-dispersion X-ray analysis apparatus (TEM-EDX) that is attached to a TEM may be used for component analysis of the sea portion and the island portions.

In addition, since the resin composition of the resin molded body of sample No. 1 contains fillers such as glass fibers and glass flakes, the resin molded body has excellent strength and is not likely to warp. Since a suitable amount of the above-described fillers is included, the resin molded body of sample No. 1 has excellent strength and is not likely to warp. Note that the filler content of the resin molded body may be measured by, for example, heating the resin molded body to volatilize and remove the resin component and the like, and extracting the above-described fillers.

### 4. Test Example 2

Samples obtained by injection-molding resin compositions of various compositions in metal members were produced, and the warping state of the resin molded bodies were examined.

4-1. Production of Samples

The metal members here are metal plates that are composed of ADC12 and are manufactured through die casting, and are commercially-available metal members. ADC 12 is an Al-based alloy that contains Si in an amount of 9.6 mass % to 12.0 mass %. A through hole is provided in the metal plate, and the resin molded body is formed through injection molding so as to be continuous inside and outside of the through hole. This metal plate is a side wall 21 of the case 2 shown in FIG. 3, and imitates a location including a through hole 22.

After sandblasting is implemented on one surface of the above-described metal plate, a commercially-available adhesive (here, epichlorohydrin rubber) is applied to the region around the through hole on the above-described one surface. After the application, the metal plate is held in a 150° C. thermostatic oven for 30 minutes to pre-cure the adhesive, and thus the half-cured adhesive layer is formed.

The resin composition of the composition shown in FIG. 2 is injection-molded (insert-molded) from the one surface of the metal plate including the above-described half-cured adhesive layer, and thus the resin molded body is produced. This resin molded body imitates the hood portion 5 shown in FIG. 1 and the like. Specifically, the tube-shaped main body portion and the ring-shaped outer flange portion are molded on the one surface of the metal plate. The ring-shaped insertion portion is molded in the through hole. The ring-shaped inner flange portion is molded on the other surface of the metal plate. No joining portion is formed. The exteriors of the main body portion and the outer flange portion are similar to those in FIG. 1, and the outer shape of the external flange portion is a rectangular shape. Note that the thickness of the adhesive layer is 0.2 mm.

The resin composition of sample No. 1 is the same as the resin composition of sample No. 1 of Test Example 1. As described above, after the resin composition of sample No. 1 is sufficiently mixed, the resin composition is sufficiently dried and then injection molding is performed.

The resin composition of sample No. 11 is the same as the resin composition of sample No. 11 of Test Example 1.

The resin compositions of samples No. 13 and No. 14 are commercially-available resin compositions that both contain PBT and an elastomer, but do not contain PET.

The resin composition of sample No. 13 contains PBT and further contains only glass fibers as a filler. The content of the filler is 30 parts by mass. The resin composition of sample No. 13 contains epoxy resin.

The resin composition of sample No. 14 contains PBT and polystyrene (PS) and further contains only glass fibers as a filler. The content of the filler is 30 parts by mass. The resin composition of sample No. 14 does not contain epoxy resin.

4-2. Measurement of Warping Amount

After the produced samples were injection-molded, they were held at room temperature (here, about 20° C.) for 1 day or more, and then the warping amount of the outer flange portion was measured using a commercially-available transmissive sensor. Here, using the one surface of the metal plate on which the outer flange portion is provided as a reference position (0 mm), the maximum distance (mm) from the one surface of the metal plate is measured for the four corner portions of the outer flange portion. The maximum distance is the warping amount (mm). The warping amounts (mm) of the four corner portions and their average values (mm) are shown in Table 2. It can be said that the smaller the warping amounts and the average value are, the less likely the resin molded body is to warp.

TABLE 2

| Sample No. | | 1 | 11 | 13 | 14 |
|---|---|---|---|---|---|
| Resin | Resin | PBT + | PBT + | PBT | PBT + |
| composition | | PET | PC | | PS |
| | Filler | GS + GF | GF + GS | GF | GF |
| | Content | | | | |
| | (parts by | 40 | 40 | 30 | 30 |
| | mass) | | | | |
| | Elastomer | Present | Not present | Present (*) | Present |
| Warping | 1 | 0.193 | 0.190 | 0.279 | 0.265 |
| amount | 2 | 0.035 | 0.060 | 0.108 | 0.112 |
| (mm) | 3 | 0.127 | 0.133 | 0.258 | 0.219 |
| | 4 | 0.051 | 0.063 | 0.108 | 0.109 |
| | Average | 0.102 | 0.112 | 0.188 | 0.176 |

As shown in Table 2, it is understood that in the resin molded body of sample No. 1, the warping amounts of the four corner portions are small, and in particular, the average value is small, and thus the resin molded body of sample No. 1 is less likely to warp compared to samples No. 11 to No. 14. The warping amounts of sample No. 1 are smaller than those of sample No. 11. Because of this, it can be said that the resin composition containing PET in addition to PBT is not likely to warp even if provided in contact with metal. Also, it is thought that if the resin composition contains an elastomer, the resin molded body will be even less likely to warp. The warping amounts of samples No. 1 and No. 11 are smaller than those of samples No. 13 and No. 14. Because of this, it is thought that if the resin composition contains glass flakes, the resin molded body will be even less likely to warp.

### 5. Test Example 3

Bondability between a metal member and a resin molded body via an adhesive layer was checked by producing samples obtained by injection-molding resin compositions of various compositions in metal members on which adhesive layers were formed.

5-1. Production of Samples

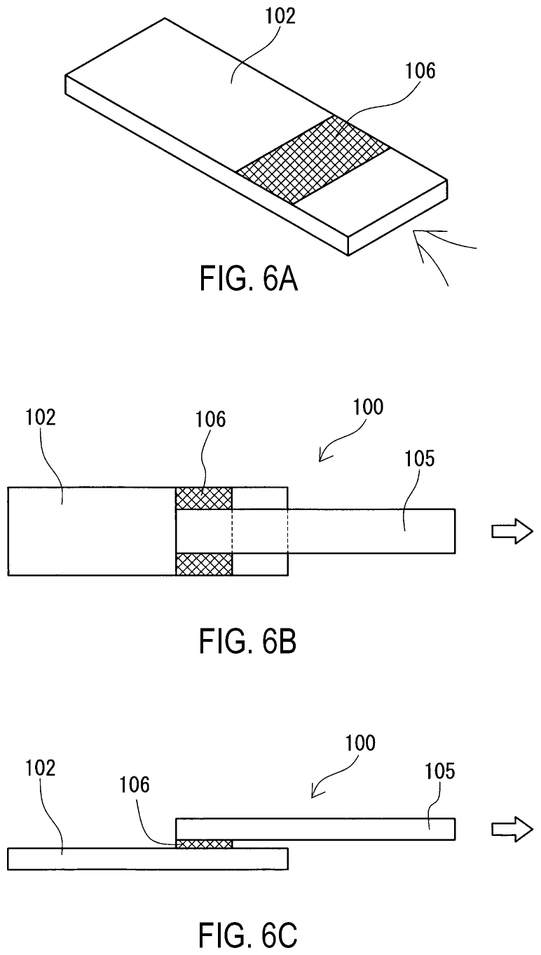

In this test, as shown in FIGS. 6B and 6C, test pieces 100 including metal pieces 102, adhesive layers 106, and resin compositions 105 are produced. FIG. 6B shows a state in which the test pieces 100 are viewed in plan view from the thickness direction of the metal pieces 102. FIG. 6C shows a state in which the test piece 100 is viewed from the side from a direction orthogonal to the thickness direction of the metal piece 102 (or the direction in which the metal piece 102 and the resin molded body 105 are stacked). In FIGS. 6A to 6C, the adhesive layer 106 is indicated with cross-hatching to facilitate comprehension. Also, in FIG. 6C, the adhesive layer 106 is shown with a thickness that is greater than its actual thickness.

The metal piece 102 is a metal plate of a die-cast member composed of commercially-available ADC12, similarly to Test Example 2. Also, the metal piece 102 is a rectangular board with a length of 50 mm, a width of 20 mm, and a thickness of 2 mm. After sandblasting is implemented on the one surface of the metal piece 102, an adhesive layer 106 with a length of 10 mm, a width of 20 mm, and a thickness of 0.2 mm is formed at a position located 10 mm away from one edge in the long-side direction (one short side edge) of the metal piece 102 (FIG. 6A). Similarly to Test Example 2, the adhesive layer 106 is formed by applying a commercially-available adhesive (epichlorohydrin rubber), and thereafter holding it at 150° C. for 30 minutes. The resin molded body 105 is formed through injection molding (insert molding) so as to overlap with the half-cured adhesive layer 106 (see the arrow in FIG. 6A). The resin molded body 105 is a rectangular plate with a length of 50 mm, a width of 10 mm, and a thickness of 2 mm. The resin molded body 105 is formed on the metal piece 102 (FIG. 6C) such that the one edge (one short side edge) of the resin molded body 105 overlaps the edge of the adhesive layer 106 (FIG. 6B). The test piece 100 is formed by stacking the metal piece 102, the adhesive layer 106, and the resin molded body 105 in the stated order. One end of the stacked body is formed by one end portion of the metal piece 102. The other end of the above-described stacked body is constituted by the other end portion of the resin molded body 105.

The resin composition of sample No. 1 is the same as the resin composition of sample No. 1 of Test Example 1. As described above, after the resin composition of sample No. 1 is sufficiently mixed, the resin composition is sufficiently dried and then injection molding is performed.

The resin compositions of samples No. 11 and No. 12 are the same as the resin compositions of samples No. 11 and No. 12 of Test Example 1.

The resin compositions of samples No. 13 and No. 14 are the same as the resin compositions of samples No. 13 and No. 14 of Test Example 2.

The resin compositions of samples No. 15 to No. 18 are commercially-available resin compositions containing PBT, and do not contain PET. The resin compositions of samples No. 15 to No. 18 further contain only glass fibers as the filler. The contents of the fillers are shown in Table 3 (15 parts by mass to 30 parts by mass). The resin compositions of samples No. 15 to No. 17 do not contain an elastomer. The resin composition of sample No. 18 contains an elastomer. The resin compositions of samples No. 15 and No. 16 do not contain epoxy resin. The resin compositions of samples No. 17 and No. 18 contain epoxy resin.

5-2. Shear Tension Test

After the produced test pieces 100 are injection-molded, the test pieces 100 are held at room temperature (here, about 20° C.) and are left at rest for one day, and thereafter a shear tension test is performed with an autograph including a commercially-available thermostatic oven. The test conditions are shown below.

Test environment: −40° C. (low temperature), 125° C. (high temperature)

Tension speed: 10 mm/min

Measurement number (N number): N=5 in each test environment.

Here, in the above-described test environment, a shear adhesive strength (kPa) and shear strain (%) are obtained for each test piece 100, and furthermore, the average value of 5 tests is obtained for each test piece 100.

The shear adhesion strength (kPa) is obtained in conformity with JIS K 6850 (1999, Method for testing tensile shear adhesion strength between an adhesive and a rigid adherend). Specifically, the shear adhesion strength is obtained using (maximum load during fracturing)/(adhesion surface area). The adhesion surface area is 10 mm×10 mm=100 mm².

The shear strain (%) of the adhesive layer 106 is obtained using [(displacement amount during fracturing)/(thickness to (mm) of adhesive layer 106 before test)]×100. The displacement amount (mm) during fracture in this context is the distance by which the end portion of the resin molded body 105 moves from the position prior to the test until fracturing.

The resin composition of sample No. 16 has conventionally been used as the constituent material of the connector. Here, using the shear adhesion strength and the shear strain of sample No. 16 as reference values (1.00), relative values of the shear adhesion strengths and the shear strain of the samples are shown in Table 3. If a relative value is greater than 1, it can be said that the shear adhesion strength is higher and the shear strain is greater than those of the sample No. 16. Such a test piece 100 can be said to have excellent adherability with the resin molded body 105 and the adhesive layer 106.

TABLE 3

| Sample No. | | 11 | 12 | 13 | 14 | 15 | 16 | 17 | 18 | 1 |
|---|---|---|---|---|---|---|---|---|---|---|
| Resin | Resin | PBT + PC | PBT + AS | PBT | PBT + PS | PBT | PBT | PBT | PBT | PBT + PET |
| composition | Filler | GF + GS | GF | GF | GF | GF | GF | GF | GF | GF + GS |
| | Content | 40 | 30 | 30 | 30 | 15 | 30 | 30 | 30 | 40 |
| | (parts by | | | | | | | | | |
| | mass) | | | | | | | | | |
| | Elastomer | Not | Not | Present | Present | Not | Not | Not | Present | Present |
| | | present | present | (*) | | present | present | present | (*) | |
| | | | (*) | | | | | (*) | | |
| Shear | −40° C. | 0.36 | 0.68 | 0.68 | 1.43 | 1.01 | 1.00 | 1.00 | 1.03 | 1.35 |
| adhesion | 125° C. | 0.96 | 0.40 | 0.56 | 0.96 | 0.40 | 1.00 | 0.48 | 1.40 | 5.00 |
| strength | | | | | | | | | | |
| Shear | −40° C. | 0.43 | 0.79 | 0.71 | 1.36 | 1.19 | 1.00 | 1.04 | 1.03 | 1.25 |
| strain | 125° C. | 2.82 | 2.15 | 1.94 | 2.25 | 2.08 | 1.00 | 0.51 | 2.25 | 5.55 |

As shown in Table 3, at both low temperatures and high temperatures, sample No. 1 has a higher shear adhesion strength and a greater shear strain than sample No. 16. Because of this, it can be said that sample No. 1 has more excellent adherability with the resin molded body and the adhesive layer, and has more excellent bondability with the resin molded body and the metal member, compared to a general-purpose connector. Samples No. 11 to No. 18 (excluding No. 16) have smaller shear adhesion strengths and shear strain than sample No. 1, or are inferior to No. 16 in some respects. Because of this, it can be said that the resin composition containing PET in addition to PBT is not likely to separate from the metal even if subjected to a heat cycle, and excellent adhesion between the resin molded body and the metal is achieved due to the adhesive layer being interposed when the resin composition is provided in contact with the metal. An improvement in sealability achieved by the adhesive layer can also be expected.

The above-described Test Examples 1 to 3 indicate that cracks are not likely to occur in the resin molded body formed by injection-molding the resin composition containing PET in addition to PBT in contact with metal, even in a usage environment that is repeatedly subjected to a heat cycle. Also, it is indicated that warping is not likely to occur in the above-described resin molded body. Furthermore, it is indicated that the above-described resin molded body also has excellent adhesion with metal via the adhesive layer, even in a usage environment that is subjected to a heat cycle. It can be said that this above-described resin molded body can be suitably used in a resin member for an application in which the member is arranged at a location near an engine, such as a location directly above an engine, for example, the hood portion and the like of the connector-equipped case of the embodiment.

The present disclosure is not limited to these illustrative examples. For example, in the above-described Test Examples 1 to 3, the composition (PBT content, type and content of filler, etc.), structure, and the like of the resin composition, the composition of the metal, and the composition of the adhesive can be changed.

What is claimed is:

1. A connector-equipped case comprising:
a case that includes a through hole; and
a connector fixed to the case, the connector including:
a core that supports a plurality of terminals; and
a hood that is formed by forming a region around the through hole of the case and a portion of the core in one piece,
wherein a constituent material of the hood is a resin composition containing polybutylene terephthalate and polyethylene terephthalate.

2. The connector-equipped case according to claim 1, wherein in the resin composition, the content of the polybutylene terephthalate is 150 parts by mass or more and 400 parts by mass or less, with respect to 100 parts by mass of the polyethylene terephthalate.

3. The connector-equipped case according to claim 1, wherein
the resin composition further contains a filler, and
the filler includes at least one of glass fibers and glass flakes.

4. The connector-equipped case according to claim 3, wherein the content of the filler is 20 parts by mass or more and 60 parts by mass or less, with respect to 100 parts by mass of the resin composition.

5. The connector-equipped case according to claim 1, wherein the resin composition further contains an elastomer.

6. The connector-equipped case according to claim 1, wherein
a phase structure of the resin composition is a sea-island structure, and
a sea portion of the sea-island structure mainly contains the polybutylene terephthalate, and island portions of the sea-island structure mainly contain the polyethylene terephthalate.

7. The connector-equipped case according to claim 1, wherein a constituent material of the core is the resin composition.

8. The connector-equipped case according to claim 1, wherein the case is a die-cast member.

9. The connector-equipped case according to claim 8, wherein a constituent material of the case is an aluminum-based alloy.

10. The connector-equipped case according to claim 9, wherein the aluminum-based alloy contains Si in an amount of 1 mass % or more and 30 mass % or less.

11. The connector-equipped case according to claim 1, wherein the case includes a fixing piece that is used for attachment to an engine.

12. The connector-equipped case according to claim 1, wherein the connector-equipped case is attached directly above the engine.

13. The connector-equipped case according to claim 1, wherein a circuit board connected to ends on one side of the terminals performs control of at least one of fuel injection of the engine and ignition of the engine.

14. The connector-equipped case according to claim 11, wherein the engine is an engine of an automobile.

15. A connector-equipped wire harness comprising:
the connector-equipped case according to claim 1; and
a wire harness connected to ends of the terminals,
wherein the overall length of the wire harness is less than 800 mm.

16. An engine control unit comprising:
the connector-equipped case according to claim 1; and
the circuit board that is stored in the case and is connected to the ends on one side of the terminals.
